(19) United States
(12) Patent Application Publication
(10) Pub. No.: US 2025/0102573 A1
(43) Pub. Date: Mar. 27, 2025

(54) SYSTEM AND METHOD FOR DECIMATED SWEEP MEASUREMENTS OF A DEVICE UNDER TEST USING MACHINE LEARNING

(71) Applicant: Tektronix, Inc., Beaverton, OR (US)

(72) Inventors: John J. Pickerd, Hillsboro, OR (US); Kan Tan, Portland, OR (US); Jamel Benbrik, Broomfield, CO (US)

(21) Appl. No.: 18/829,842

(22) Filed: Sep. 10, 2024

Related U.S. Application Data
(60) Provisional application No. 63/585,204, filed on Sep. 25, 2023.

(51) Int. Cl. G01R 31/3183; G01R 31/319

(52) U.S. Cl. CPC G01R 31/318357; G01R 31/31912

(57) ABSTRACT

A test and measurement instrument includes one or more ports to allow the test and measurement instrument to receive a signal from a device under test (DUT), a user interface to allow the user to send inputs to the test and measurement instrument and receive results, and one or more processors configured to acquire the signal from the DUT, make measurements on the signal to create a decimated measurement set, convert the decimated measurement set into a tensor, send the tensor to a machine learning network, and receive a pass/fail value from the machine learning network. A method includes acquiring a signal from a device under test (DUT), making measurements on the signal to create a decimated measurement set, convert the decimated measurement set into a tensor, sending the tensor to a machine learning network, and receiving a pass/fail value from the machine learning network.

### CROSS-REFERENCE TO RELATED APPLICATIONS

This disclosure is a non-provisional of and claims benefit from U.S. Provisional Application No. 63/585,204, titled “SYSTEM AND METHOD FOR DECIMATED SWEEP MEASUREMENTS OF A DEVICE UNDER TEST USING MACHINE LEARNING,” filed on Sep. 25, 2023, the disclosure of which is incorporated herein by reference in its entirety.

### TECHNICAL FIELD

This disclosure relates to test and measurement systems and methods, and more particularly to applying machine learning to measure characteristics of signals from devices under test.

### BACKGROUND

When measuring performance of devices under test (DUT), the user typically performs a “full sweep” of the measurements. Examples of the measurements include, but are not limited to, various current and/or voltage measurements. The term “full sweep” as used here means measurements of all the possible measurement points in the data. Performing this many measurements takes a long period of time. Generally, the measurements allow the user testing the device to make a determination of pass or fail for the DUT.

Users will attempt to reduce the number of measurements needed in order to speed up the collection process of the data. However, the user needs to balance the desire for faster measurements with the need for accurate determinations of pass/fail.

### BRIEF DESCRIPTION OF THE DRAWINGS

FIG. 1 shows an embodiment of a training configuration for a test and measurement system.

FIG. 2 shows an embodiment of a runtime configuration for a test and measurement system.

FIG. 3 shows an embodiment of a test and measurement instrument.

### DESCRIPTION

Generally, embodiments herein associate full sweep measurements, and a pass/fail result, with a decimated version of the sweep measurements. This allows users to speed up the acquisitions of measurement data. Rather than just decimating the measurements and basing a pass/fail result on the decimated measurements, the system will instead train a neural network which uses input labels of pass/fail based on the slower full sweep data set and associate the labels with the decimated set of measurements taken out of the full sweep set. Allowing a smaller decimated set while maintaining accuracy would speed up the process even more.

One example use case of some embodiments of the disclosure includes a manufacturing situation where multiple measurements must be made on a device under test (DUT) and then processed to indicate pass/fail or other classifications of failure type, etc. For example, one may want to measure IV, current versus voltage, curves for a component. This may require measurements of many points taking a long period of time. In addition, measurements of data like a transfer function, such as s21 frequency response type of data, may require many points, also very time consuming.

A user or programmer of such a test system will naturally attempt to reduce the number of measurements needed in order to speed up the collection process of that data. The embodiments of this disclosure enable the user to reduce the data measurement set even further by using a neural network. The embodiments involve training the machine learning system on the full data set to create the training labels but associate the measurements with the reduced data set. The discussion here refers to the reduced data set as the “decimated” data set.

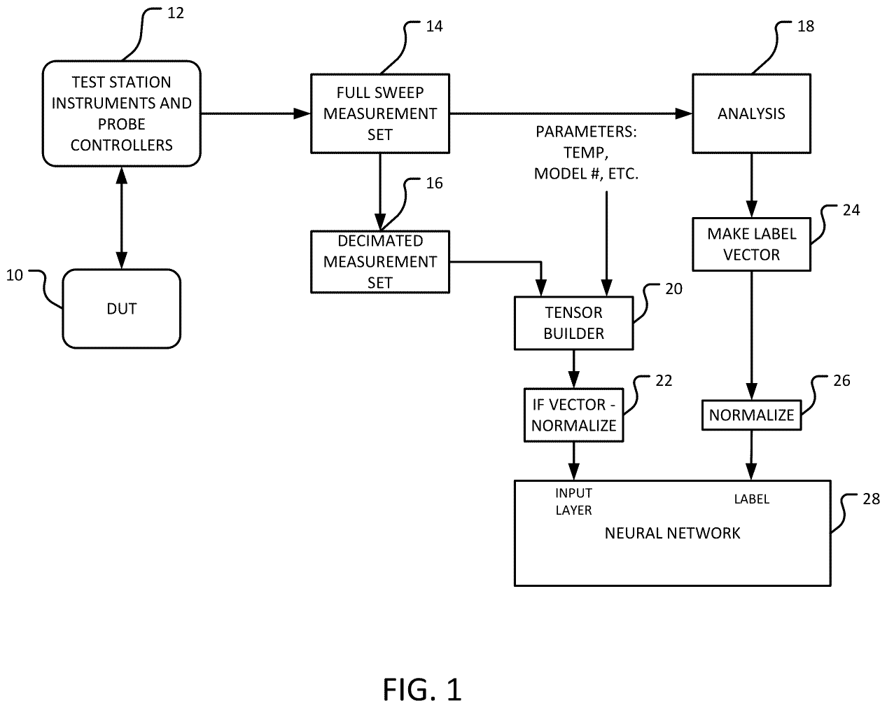

FIG. 1 shows an embodiment of a system configuration for training a machine learning network to use decimated measurements to provide pass/fail results for devices under test (DUT). This block diagram represents the system configuration for training the neural network, according to some example embodiments. The label on the neural network block during training will be an input and will be the pass/or fail prediction value. This label can have a value of 1.0 for pass and 0 for fail. The neural network will be trained to associate that label with the other inputs.

In some embodiments, the DUT may be an integrated circuit die, such as a silicon photonics transceiver wafer die, for example. According to some of these embodiments, the other inputs to the neural network may consist of six sets of measurements that are obtained from the die through a test station setup. Other examples of DUTs include electronic devices, optical devices such as optical switches, and many others. Examples of the measurements include current-voltage (I-V) curves, s parameters (s11, s12, s21 and s22) in photonics, or other characteristics.

In addition, some embodiments may employ other parameters such as ambient temperature, or a model number for the wafer/die types, etc., as inputs to the neural network. Training the neural network requires a sufficient amount of data, meaning enough samples of DUTs to cover the expected distribution of DUT characteristics that would be seen during manufacturing. A sufficient amount of data exists when the neural network can be trained to be able to make predictions to within a predetermined threshold of accuracy.

FIG. 1 shows an embodiment of a training configuration for a system that can use decimated measurements for pass/fail of DUTs. A test and measurement instrument makes up a part of the test station 12. The test station connects to DUT 10 to receive signals from the DUT from which the test and measurement instrument can obtain measurement data such as waveforms. The test and measurement instrument, referred to here as “instrument,” performs a full sweep of measurements on each DUT to produce a full sweep measurement set at 14. The instrument then reduces each full sweep measurement down to a defined set of reduced measurements 16, referred to here as a “decimated measurement set.”

In one embodiment, a tensor builder 20 converts each decimated measurement into a tensor, either a one-dimensional data vector or a tensor image, such as a red-green-blue (RBG) image. More information about tensor images can be found in U.S. patent application Ser. No. 17/701,186, “OPTICAL TRANSMITTER TUNING USING MACHINE LEARNING AND REFERENCE PARAMETERS,” filed Mar. 22, 2021, and U.S. patent application Ser. No. 17/747,954, “SHORT PATTERN WAVEFORM DATABASE MACHINE LEARNING FOR MEASUREMENT,” filed May 21, 2021, both of which are incorporated herein in their entirety.

When the tensor builder 20 produces image tensors, no external normalization block is needed. When the tensor building produces a single input vector, then the normalization block 22 would be needed to represent the data in the range of 0 to 1 for input to the first neural net layer. For the label input the external normalize block may not be needed if the label is 1 for pass and 0 for fail. In this case, the output of the label vector block 24 would go directly to the neural network. However, if it is desirable to have the network also predict other numerical values in addition to pass fail then the normalization block may be needed depending on the nature of the variables.

Other information, such as the temperature of the DUT during testing, the model #of the DUT, and any other information, may also be added to, or incorporated or encoded in, the tensor produced by tensor builder 20. The full sweep measurement that corresponds to the decimated measurement undergoes analysis at 18 to see if the DUT would pass or fail. Analysis block 18 applies the algorithms needed to analyze the full sweep data set and determine what the pass/fail labels shall be.

The pass or fail label will also be converted into a label vector at 24. This may undergo normalization at 26 for input to the neural network 28. As discussed above, depending upon the values used for the pass/fail the normalization block 26 would not be needed. The decimated measurement tensor is assigned the label of pass/fail. This will allow the machine learning network to associate the decimated measurements with a pass or fail label. Ultimately, this will result in the machine learning network 28 being able to determine pass or fail from the decimated measurement during runtime.

In summary, the training process includes characterizing a sufficient number of DUTs, such as semiconductor dies, performing a full sweep of data points for each DUT. Each full sweep of data points undergoes analysis to identify pass or fail. The full sweep of data points is decimated to produce the decimated data. The decimated data, and any other data, would then go to the tensor builder and then normalized if needed. The resulting tensor and the label tensor then go to the neural network for training.

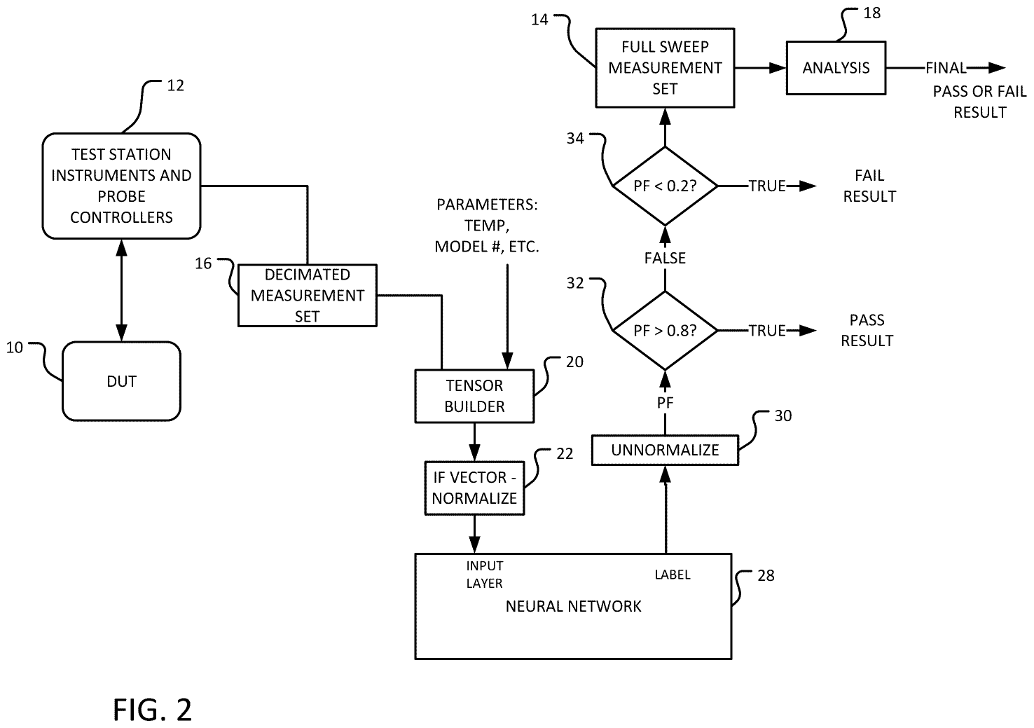

FIG. 2 shows an embodiment of a runtime configuration of the test system. In the configuration of FIG. 2, the full sweep measurement set becomes an option for failed DUTs. The main process flow involves creating the decimated data, building tensors, and sending the tensor input to the neural network. This configuration does not collect the full sweep data set. The test station block would only spend time to collect the decimated data measurement set. After the neural network receives the decimated data, it provides a value that indicates pass or fail (PF).

The PF result may take many forms and may be further analyzed to make a more precise definition. The result may undergo un-normalizing at 30, or not, depending on if the pass/fail range is between 0 and 1, as mentioned above. Further analysis may comprise determining a threshold that indicates pass or fail, or one threshold for pass and one for fail. The label output from the neural network could be represented from a regression layer in the neural network. When the expected value output for pass is 1.0 and the value for fail is 0.0, or in any embodiment where the range is from 0 to 1, the unnormalize block 30 will not be needed. The neural network may output a fractional value anywhere between 0 and 1, representing a degree of passing or failing.

In the embodiment of FIG. 2, the pass threshold is if the PF value is greater than or equal to 0.8 at 32, in which case the DUT passes. If the PF value is less than or equal to 0.2 at 34, the DUT fails. Other options could include a single threshold, with values above it being a pass, and those below being a fail.

A problem may occur if the determination uses separate thresholds, and the PF value lies between the separate thresholds. This results in an unclear or “fuzzy” result. For example, the DUT did not pass at 32, and did not fail at 34. At that point, the option exists to perform a full sweep measurement set such as at 14 in FIG. 1. The full sweep then undergoes analysis at 18, and the final result is obtained.

The pass/fail output from the neural network then determines whether or not to package the die or otherwise move the DUT through the manufacturing process. If the result is fail, then the die or DUT is discarded. If the result is pass, then the die shall be placed into a package, or the DUT will be passed along into the manufacturing process. In summary, threshold levels may be assigned such as the label must be greater than 0.8 to pass, and less than 0.2 to fail, and thresholds other than 0.8 and 0.2 may be used. By restricting the use of the full sweep only for unclear results, the process becomes much faster.

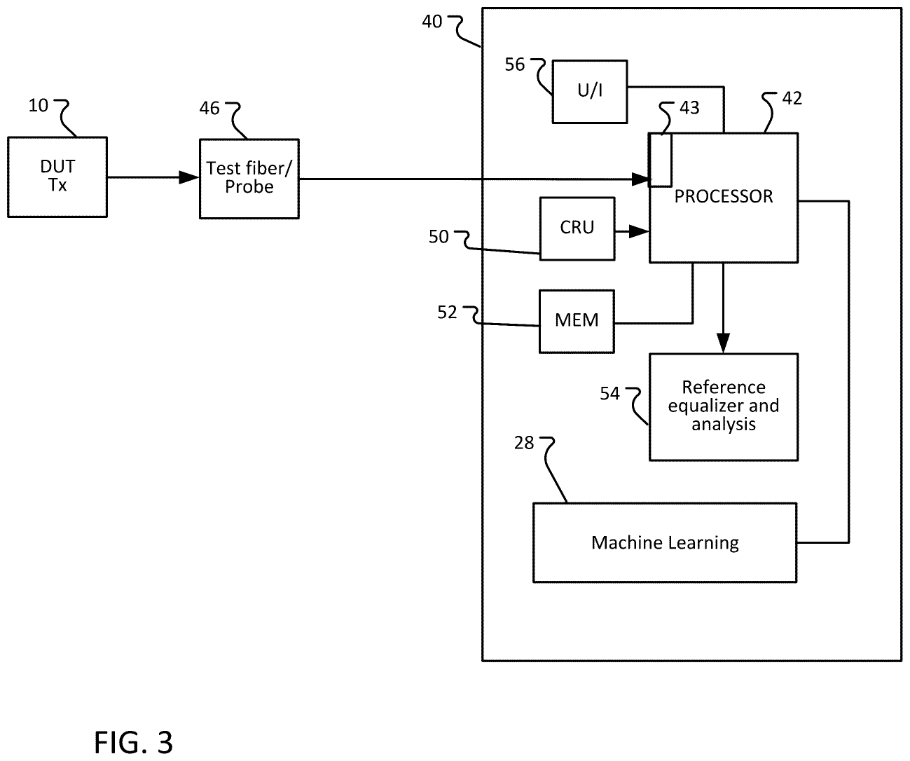

A device under test (DUT) generates a signal that a test and measurement instrument captures. FIG. 3 shows an embodiment of such an instrument. FIG. 3 shows an embodiment of a testing setup in the instance of the test and measurement instrument measuring or testing the DUT 10. The testing setup may include a test and measurement instrument 40, which may comprise an oscilloscope. The test and measurement instrument 40 receives a signal from the DUT 10 directly or through an instrument probe 46. In the case of an optical transmitter DUT, the probe will typically comprise a test fiber coupled to an optical to electrical converter 46, not shown, that provides a signal to the test and measurement instrument through one or more ports 43. Two ports may be used for differential signaling, while one port is used for single-ended signaling. The signals are sampled and digitized by the instrument to become waveforms. A clock recovery unit (CRU) 50 may recover the clock signal from the data signal if the test and measurement instrument 40 comprises a sampling oscilloscope for example. A software clock recovery can be used on a real-time oscilloscope.

The test and measurement instrument has one or more processors represented by processor 42, a memory 52 and a user interface 56. The memory may store executable instructions in the form of code that, when executed by the processor, causes the processor to perform tasks. User interface 56 of the test and measurement instrument allows a user to interact with instrument 40, such as to input settings, configure tests, etc. The test and measurement instrument may also include a reference equalizer and analysis module 54.

The embodiments here employ machine learning in the form of a machine learning network 28, such a deep learning network. The machine learning network may include a processor that has been programmed with the machine learning network as either part of the test and measurement instrument, or to which the test and measurement instrument has access. As test equipment capabilities and processors evolve, the one or more processors such as 42 may include both. The machine learning system may take the form of programmed models operating on one or more of the processors. The processors may also be configured to execute code to perform the methods of the embodiments.

The embodiments provide an instrument and generalized method that uses machine learning to make pass/fail predictions based on a decimated set of measurements. The network is trained using pass/fail labels derived from a set of full sweep measurements. This results in speeding up the measurement time by only collecting data for the decimated sweep measurement set. If the prediction is fuzzy in between pass and fail, then the full data sweep could be performed to make the final prediction. Alternatively, the DUTs that lie under the pass threshold may also be discarded.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement instrument, comprising: one or more ports to allow the test and measurement instrument to receive a signal from a device under test (DUT); a user interface to allow the user to send inputs to the test and measurement instrument and receive results; and one or more processors configured to execute code that causes the one or more processors to: acquire the signal from the DUT; make measurements on the signal to create a decimated measurement set; convert the decimated measurement set into a tensor; send the tensor to a machine learning network; and receive a pass/fail value from the machine learning network.

Example 2 is the test and measurement instrument of Example 1, wherein the code that causes the one or more processors to receive a pass/fail value from the machine learning network causes the one or more processors to receive the pass/fail value as a value between 1.0 and 0.0 inclusive.

Example 3 the test and measurement instrument of either of Examples 1 or 2, wherein the one or more processors are further configured to execute code that causes the one or more processors to compare the pass/fail value to a threshold to determine whether the DUT passes or fails.

Example 4 the test and measurement instrument of Example 3, wherein the DUT passes when the pass/fail value is greater than or equal to 0.8, and the DUT fails when the value is less than or equal to 0.2.

Example 5 is the test and measurement instrument of any of Examples 1 through 4, wherein the one or more processors are further configured to execute code to cause the one or more processors to perform a full sweep of measurements on the DUT when the pass/fail indication is unclear.

Example 6 is the test and measurement instrument of Example 5, wherein a user provides an input through the user interface choosing to perform the full sweep of measurements.

Example 7 is the test and measurement instrument of any of Examples 1 through 6, wherein the one or more processors are further configured to execute code that causes the one or more processors to train the machine learning network.

Example 8 is the test and measurement instrument as claimed in claim 7, wherein the code that causes the one or more processors to train the machine learning network comprises code that causes the one or more processors to: characterize a sufficient number of DUTs by performing a full sweep of data points for each DUT to produce a sufficient amount of data for training; perform an analysis of each full sweep of data points to determine if the full sweep of the data points is a pass or fail result; use the pass or fail result as a label for training the machine learning network; decimate each full sweep of data points to produce the decimated data set corresponding to each full sweep of data points; and train the machine learning network to associate each decimated data set with the pass or fail result label of a corresponding full sweep of data points.

Example 9 is the test and measurement instrument of Example 8, wherein the one or more processors are further configured to execute code that causes the one or more processors to convert the decimated data set into a tensor prior to training the machine learning network.

Example 10 is a method, comprising: acquiring a signal from a device under test (DUT); making measurements on the signal to create a decimated measurement set; converting the decimated measurement set into a tensor; sending the tensor to a machine learning network; and receiving a pass/fail value from the machine learning network.

Example 11 is the method of Example 10, wherein receiving a pass/fail value from the machine learning network causes the one or more processors to receive the pass/fail value as a value between 1.0 and 0.0 inclusive.

Example 12 is the method of either of Examples 10 or 11, further comprising comparing the pass/fail value to a threshold to determine whether the DUT passes or fails.

Example 13 is the method of Example 12, wherein the DUT passes when the pass/fail value is greater than or equal to 0.8, and the DUT fails when the value is less than or equal to 0.2.

Example 14 is the method of any of Examples 10 through 13, further comprising performing a full sweep of measurements on the DUT when the pass/fail indication is unclear.

Example 15 is the method of any of Examples 10 through 13, wherein a user provides an input through a user interface choosing to perform the full sweep of measurements.

Example 16 is the method of any of Examples 10 through 13, further comprising training the machine learning network.

Example 17 is the method of Example 16, wherein training the machine learning network comprises: characterizing a sufficient number of DUTs by performing a full sweep of data points for each data set to produce a sufficient amount of data for training; performing an analysis of each full sweep of data points to determine if the full sweep of data points is a pass or fail result; using the pass or fail result as a label for training the machine learning network; decimating each full sweep of data points to produce the decimated data set corresponded to each full sweep of data points; and training the machine learning network to associate each decimated data set with the pass or fail result label of a corresponding full sweep of data points.

Example 18 is the method of Example 17, further comprising converting the decimated data set into a tensor prior to training the machine learning network.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

The invention claimed is:

1. A test and measurement instrument, comprising:
one or more ports to allow the test and measurement instrument to receive a signal from a device under test (DUT);
a user interface to allow the user to send inputs to the test and measurement instrument and receive results; and
one or more processors configured to execute code that causes the one or more processors to:
acquire the signal from the DUT;
make measurements on the signal to create a decimated measurement set;
convert the decimated measurement set into a tensor;
send the tensor to a machine learning network; and
receive a pass/fail value from the machine learning network.

2. The test and measurement instrument as claimed in claim 1, wherein the code that causes the one or more processors to receive a pass/fail value from the machine learning network causes the one or more processors to receive the pass/fail value as a value between 1.0 and 0.0 inclusive.

3. The test and measurement instrument as claimed in claim 1, wherein the one or more processors are further configured to execute code to cause the one or more processors to compare the pass/fail value to a threshold to determine whether the DUT passes or fails.

4. The test and measurement instrument as claimed in claim 3, wherein the DUT passes when the pass/fail value is greater than or equal to 0.8, and the DUT fails when the value is less than or equal to 0.2.

5. The test and measurement instrument as claimed in claim 1, wherein the one or more processors are further configured to execute code to cause the one or more processors to perform a full sweep of measurements on the DUT when the pass/fail indication is unclear.

6. The test and measurement instrument as claimed in claim 5, wherein a user provides an input through the user interface choosing to perform the full sweep of measurements.

7. The test and measurement instrument as claimed in claim 1, wherein the one or more processors are further configured to execute code that causes the one or more processors to train the machine learning network.

8. The test and measurement instrument as claimed in claim 7, wherein the code that the one or more processors to train the machine learning network comprises code that causes the one or more processors to:
characterize a sufficient number of DUTs by performing a full sweep of data points for each DUT to produce a sufficient amount of data for training;
perform an analysis of each full sweep of data points to determine if the full sweep of data points is a pass or fail result;
use the pass or fail result as a label for training the machine learning network;
decimate each full sweep of data points to produce the decimated data set corresponding to each full sweep of data points; and
train the machine learning network to associate each decimated data set with the pass or fail result label of a corresponding full sweep of data points.

9. The test and measurement instrument as claimed in claim 8, wherein the one or more processors are further configured to execute code that causes the one or more processors to convert the decimated data set into a tensor prior to training the machine learning network.

10. A method, comprising:
acquiring a signal from a device under test (DUT);
making measurements on the signal to create a decimated measurement set;
converting the decimated measurement set into a tensor;
sending the tensor to a machine learning network; and
receiving a pass/fail value from the machine learning network.

11. The method as claimed in claim 10, wherein receiving a pass/fail value from the machine learning network causes the one or more processors to receive the pass/fail value as a value between 1.0 and 0.0 inclusive.

12. The method as claimed in claim 10, further comprising comparing the pass/fail value to a threshold to determine whether the DUT passes or fails.

13. The method as claimed in claim 12, wherein the DUT passes when the pass/fail value is greater than or equal to 0.8, and the DUT fails when the value is less than or equal to 0.2.

14. The method as claimed in claim 10, further comprising performing a full sweep of measurements on the DUT when the pass/fail indication is unclear.

15. The method as claimed in claim 10, wherein a user provides an input through a user interface choosing to perform the full sweep of measurements.

16. The method as claimed in claim 10, further comprising training the machine learning network.

17. The method as claimed in claim 16, wherein training the machine learning network comprises:
characterizing a sufficient number of DUTs by performing a full sweep of data points for each data set to produce a sufficient amount of data for training;
performing an analysis of each full sweep of data points to determine if the full sweep of data points is a pass or fail result;
using the pass or fail result as a label for training the machine learning network;
decimating each full sweep of data points to produce the decimated data set corresponding to each full sweep of data points; and
training the machine learning network to associate each decimated data set with the pass or fail result label of a corresponding full sweep of data points.

18. The method as claimed in claim 17, further comprising converting the decimated data set into a tensor prior to training the machine learning network.
